(19) United States
(12) Patent Application Publication
(10) Pub. No.: US 2005/0067699 A1
(43) Pub. Date: Mar. 31, 2005

(54) Diffusion barrier layer for lead free package substrate

(75) Inventors: Kum Foo Leong, Kedah (MY); Chee Key Chung, Penang (MY); Kian Sin Sim, Penang (MY)

Correspondence Address: Schwegman, Lundberg, Woessner & Kluth, P.A., P.O. Box 2938, Minneapolis, MN, 55402, US

(73) Assignee: Intel Corporation

(21) Appl. No.: 10/673,605

(22) Filed: Sep. 29, 2003

(51) Int. Cl. H01L 23/48

(52) U.S. Cl. 257/737; 438/613

(57) ABSTRACT

A ball grid array device includes an array of pads made of an electrically conductive material. The array of pads is positioned on the first major surface. At least one of the array of pads includes a diffusion retarding layer to retard the rate of diffusion of the electrically conductive material from the pad. The ball grid array device also includes a binding layer for binding the diffusion retarding layer to the conductive material of the at least one pad. The ball grid array device also includes a layer of material for receiving solder placed on the diffusion retarding layer.

### FIELD OF THE INVENTION

The present invention is related to packages for semiconductor devices. More specifically, the present invention relates to an apparatus for diffusion barrier layer for lead free package substrate and a method associated with forming diffusion barrier layers for lead free package substrates.

### BACKGROUND OF THE INVENTION

The semiconductor industry has seen tremendous advances in technology in recent years that have permitted dramatic increases in circuit density and complexity, and equally dramatic decreases in power consumption and package sizes. Present semiconductor technology now permits single-chip microprocessors with many millions of transistors, operating at speeds of tens (or even hundreds) of MIPS (millions of instructions per second), to be packaged in relatively small, air-cooled semiconductor device packages. A by-product of such high density and high functionality in semiconductor devices has been the demand for increased numbers of external electrical connections to be present on the exterior of the die, and on the exterior of the semiconductor packages that receive the die, for connecting the packaged device to external systems, such as a printed circuit board.

To meet the demand for an increased number of external electrical connections, ball grid array packages and bump grid array packages were developed and are now used in many applications. The bump grid array or ball grid array (BGA) includes an array of solder bumps or balls that cover the surface of the die or semiconductor package and are used to connect the die and the semiconductor package. A typical BGA package is characterized by a large number of solder balls disposed in an array on a major surface of the package. It is not uncommon to have hundreds of solder balls in an array. The BGA package is assembled to a matching array of conductive pads. The pads are connected to other devices within a substrate, or circuitry on a circuit board. Heat is applied to reflow the solder balls (bumps) on the package, thereby wetting the pads on the substrates and, once cooled, forming electrical connections between the package and the semiconductor device contained in the package, and the substrate.

BGAs have the advantage of providing more connections between the die and the semiconductor package. BGAs also have the advantage that the size of the balls or bumps can be made smaller to provide a higher density of solder bumps or balls, and thereby a greater number of connections from a die. BGAs are formed by placing an amount of solder on a solder pad and heating the solder to a melting point. The surface tension associated with the liquid solder causes the solder to form a solder ball. The solder ball retains its shape as it cools to form a solid solder ball or bump.

In some applications, as the solder material is reflowed to form the balls or bumps, the interdiffusion process from a copper (Cu) pad is rapid and results in formation of voids in the solder ball. These voids are known as Kirkendall voids. The formation of voids is exacerbated when lead (Pb) free solder is used. In the past, most of the solder used to form the bumps or balls on the pads included lead (Pb). Currently, however, governments are requiring that the solder used to form the bumps or balls is lead-free since lead is known to be toxic to humans. The Kirkendall voids are undesirable since the structure formed generally is weaker than a ball or bump with fewer voids. In addition, the Kirkendall voids may also negatively effect the electrical performance of the solder ball and joint formed using the solder ball.

In addition, some pads have included a layer of nickel phosphorous. The phosphorus has been found to cause brittle fractures after the reflow of the solder to form solder bumps or balls. The brittle fractures may develop due to mechanical bending, which can result in a separation interface between the solder matrix and the component pad. Fatigue failure can also result in a crack propagating across the pad. These cracks or brittle fractures can result in failed solder joints, that in turn result to electrical open and failure of electronic device. Many times the failures do not occur until after a component has left the factory. The component can pass tests within the factory and then a field failure can occur. Such failures are undesirable as consumers of these components develop negative impressions of the providers of these parts. In addition, finding and fixing field failures is a very expensive and time consuming process.

### BRIEF DESCRIPTION OF THE DRAWINGS

The invention is pointed out with particularity in the appended claims. However, a more complete understanding of the present invention may be derived by referring to the detailed description when considered in connection with the figures, wherein like reference numbers refer to similar items throughout the figures, and:

FIG. 1 is an isometric view of an array of pads on a substrate, according to an embodiment of this invention.

FIG. 2 is a schematic cross-sectional view of a portion of a substrate having a pad with a surface finished with a diffusion retarding layer, according to an embodiment of this invention.

FIG. 3 is a cross-sectional view of a portion of a substrate along line 3-3 in FIG. 1, having a pad with a surface finished with a diffusion retarding layer, according to another embodiment of this invention.

FIG. 4 is a close-up schematic cross-sectional view of a substrate having a pad with a surface finished with a diffusion retarding layer, according to another embodiment of this invention.

FIG. 5 is a close-up cross-sectional view of a lead-free solder ball attached to a pad in a BGA device, according to an embodiment of this invention.

FIG. 6 is a schematic cross-sectional view of the intermetallic compound formed at and near the junction of the solder ball and the pad of the substrate, according to an embodiment of this invention.

FIG. 7 is a flow diagram of a method of forming a pad on an electronic device, according to an embodiment of this invention.

FIG. 8 is a flow diagram showing a method for forming a solder ball onto a pad of an electronic device, according to an embodiment of this invention.

The description set out herein illustrates the various embodiments of the invention, and such description is not intended to be construed as limiting in any manner.

### DETAILED DESCRIPTION

In the following detailed description of the preferred embodiments, reference is made to the accompanying drawings that form a part hereof, and in which are shown by way of illustration specific embodiments in which the invention can be practiced. The embodiments illustrated are described in sufficient detail to enable those skilled in the art to practice the teachings disclosed herein. Other embodiments can be utilized and derived therefrom, such that structural and logical substitutions and changes can be made without departing from the scope of present inventions. The following detailed description, therefore, is not to be taken in a limiting sense, and the scope of various embodiments of the invention is defined only by the appended claims, along with the full range of equivalents to which such claims are entitled.

FIG. 1 is a isometric view of a substrate 100. The substrate 100 includes a first major surface 110 and the second major surface 120. On the first major surface 110 there is an array of pads 130. The substrate 100 is prepared for receiving solder placed on each of the pads 130 or at least some of the pads 130. The substrate and the solder are heated during a reflow process. The substrate and solder is heated to a temperature where the solder melts to a liquid state. While in the liquid state surface tension of the liquid forms a solder ball. Also, during the liquid state, the solder and portions of the pad form various alloyed metals which occur at the interface between the solder ball and the pad. The various alloyed materials are also known as intermetallic compounds (IMC). Shown in FIG. 1 is the substrate with the pads before the solder or solder balls have been formed on the substrate 100. In some embodiments of the invention surface 110 may include portions of a mask while in other embodiments of the invention the first major surface 110 does not include portions of a mask.

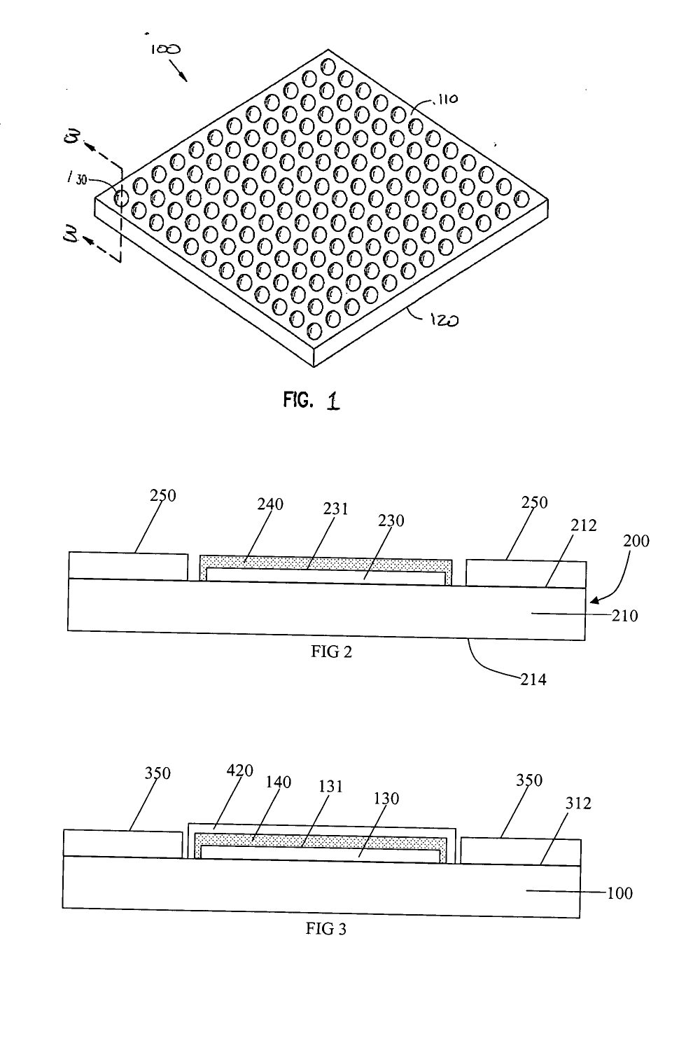

FIG. 2 is a schematic cross-sectional view of a portion of a substrate 200 having a pad 230 with a surface 231 finished with a diffusion retarding layer 240, according to an embodiment of this invention. The pad 230 is formed on a substrate 210 having a first major surface 212 and a second major surface 214. The substrate 210 is formed of a printed circuit card material such as FR4 or BT resin. A solder mask 250 is placed on to the surface 212 of the substrate 210. Once the solder mask 250 is in place, the diffusion retarding layer 240 is placed on to the surface 231 of the pad 230. The diffusion retarding layer 240 protects the pad 230 from oxidation and also retards or controls the amount of diffusion between the material of the pad 230 and the material of the solder ball (not shown) which will be positioned on the pad after solder has been placed on the pad and a reflow operation has heated the solder to the melting point. The diffusion retarding material 240 can be placed on the pad in any number of ways, including sputtering or other deposition techniques. The diffusion retarding material 240 can also be thought of as controlling the out-diffusion of the material of the pad 230. For example, the pad 230 may be formed of copper or an alloy of copper. The diffusion-retarding layer 240, therefore, controls the out-diffusion of copper from the pad into the solder material.

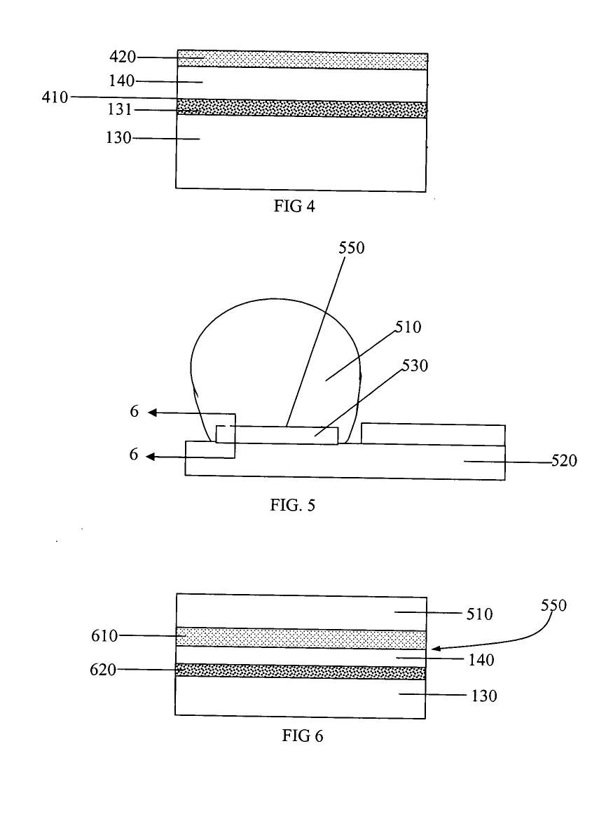

FIG. 3 is a cross-sectional view of a portion of the substrate 100 a long line 3-3 in FIG. 1, according to an embodiment of this invention. The pad 130 has a surface 131 covered by a diffusion retarding layer 140. FIG. 4 is a close up cross-sectional view of the pad 130 and the surface finish on the surface 131 of the pad, according to an embodiment of this invention. FIG. 4 is the portion of the pad 130 that is circled in FIG. 3. Now referring to both FIGS. 3 and 4, the surface finish on the pad 130 will be discussed in more detail. The pad 130 is made of copper or a copper alloy. A diffusion-retarding layer that includes a formulation of 54 Fe-29Ni/17Co is placed on the surface 131 of the copper pad 130. The diffusion-retarding layer that includes a formulation of 54 Fe-29Ni/17Co is available from Carpenter Technology Corporation, 2 Meidian Boulevard, Wyomissing, Pa. 19610-1339 U.S.A. under the trademark Kovar® (registered trademark of Carpenter Technology Corporation). The diffusion-retarding layer that includes a formulation of 54 Fe-29Ni/17Co is also indexed by a UNS number K94610 from the Carpenter Technology Corporation. The diffusion-retarding layer does not bind well to the copper pad 130. Therefore, a layer of titanium 410 is placed over the copper pad 130. Specifically a layer of titanium of approximately 80 to 120 nm is placed on to the surface 131 of the copper pad 130. The diffusion-retarding layer 140 is then placed onto the titanium layer 410. The titanium layer 410 binds the diffusion-retarding layer 140 to the copper pad 130 and specifically to the surface 131 of the copper pad. The diffusion-retarding layer is approximately 0.2 to 2.5 μm.

The diffusion-retarding layer 140 is subject to oxidation. When the diffusion-retarding layer 140 oxidizes, the solderability of the layer is compromised. A layer of gold (Au) 420 is coated or placed on top of the diffusion-retarding layer 140 to prevent oxidation of the diffusion-retarding layer 140 and to enhance the solderability of the pad 130. The gold layer 420 also enhances the solderability when a lead-free solder is used. It is anticipated that lead-free solder will be used in more applications in the future as more regulations limiting lead are promulgated by government entities. The diffusion-retarding layer 140 slows the diffusion of the copper material of the copper pad 130 during the reflow process where the substrate 100. During the reflow process, the copper pad 130, the surface treatment on the copper pad, and solder (not shown) are heated to form a solder ball, as shown in FIG. 5.

FIG. 5 is a close up, cross-sectional view of a lead free solder ball 510 attached to a pad 520 on a substrate 520. As shown in FIG. 5, there is a region depicted by a line in carrying a reference 550 where the materials from the solder pad 530 and the materials from the solder ball 510 mix to form intermetallic compounds (IMCs). One formulation for a lead free solder is SnAgCu. Without a layer of Kovar® or other layer of diffusion-retarding material, the copper from the copper pad 530 diffuses too quickly and too deeply into the material of the solder ball 510. Voids are also more readily formed when diffusion is fast and deep. The diffusion-retarding layer slows the diffusion to minimize formation of voids.

Use of the Kovar® diffusion-retarding layer also has another advantage. The diffusion-retarding layer is free of phosphorous and therefore does not form an intermetallic compound containing phosphorous which would be brittle and subject to fatigue and cracking. When the diffusion between the copper pad and the solder material is rapid, Kirkendall void formation is prevalent. When the Kovar® or diffusion controlling or diffusion retarding layer, such as layer 410 shown in FIG. 4 is used the Kirkendall formation lessens therefore, resulting in a better, more reliable electrical connection.

FIG. 6 is a cross-sectional view of the junction between the solder ball 510 and the copper pad 130 and the diffusion-retarding layer 140, according to an embodiment of this invention. As shown in FIG. 6, the region where intermetallic compounds are formed 550 actually has 2 different areas where intermetallic compounds are formed: a first region 610 where intermetallic compounds are formed between the diffusion retarding layer—TI interface and the lead-free solder of SnAgCu; and a second region 620 where intermetallic materials are formed occurs at the interface between the diffusion retarding layer 140 and the copper pad 130. Given that the lead-free solder is of the formulation SnAgCu, the intermetallic compounds found at the SnAgCu/Kovar®-TI interface include Sn—Fe (η, θ), Ni—Sn (Ni₃Sn₄); Sn—Ti (γ), Cu-γFe. Similarly at the Kovar®/TiCu interface the following intermetallic compounds are formed α-Co/Ti; Cu—Ti (γ), α-Fe—Ti (ε) Cu—Co, Cu-γFe, Cu—Ni (α₁,α₂). As can be seen, complex alloys or intermetallic compounds are formed at each of the regions 610 and 620. The formation of complex alloys indicates strong binding at the interface between the pad and the diffusion retarding layer as well as between the diffusion retarding layer and the lead-free solder. Formation of complex alloys also indicate that the diffusion retarding layer is retarding the diffusion of materials between the copper pad and the lead-free solder. The diffusion retarding layer in combination with the titanium controls Cu diffusion to prevent rapid diffusion in the formation of the kirkendall voids. The diffusion retarding layer with titanium also acts as a barrier to prevent diffusion of tin (Sn) from the lead-free solder 510 into the pad 130. Thus, the diffusion controlling or diffusion-retarding layer 140 prevents intermetallic compounds from growing at a rate that causes a spalling effect which can cause a separation from the pad and other failures at a layer time.

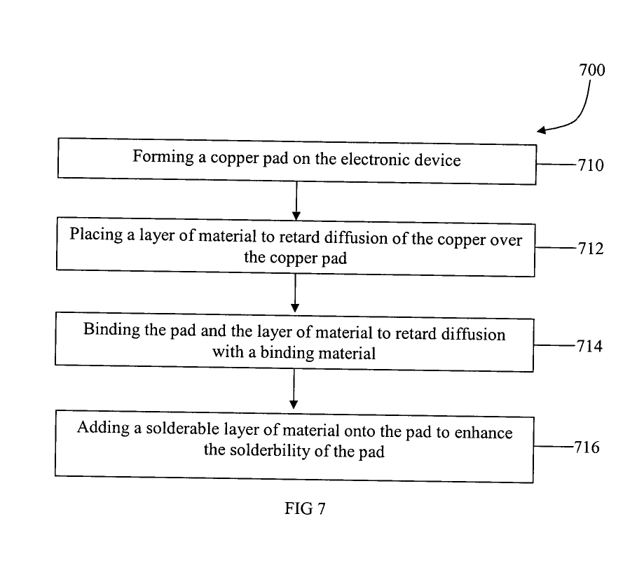

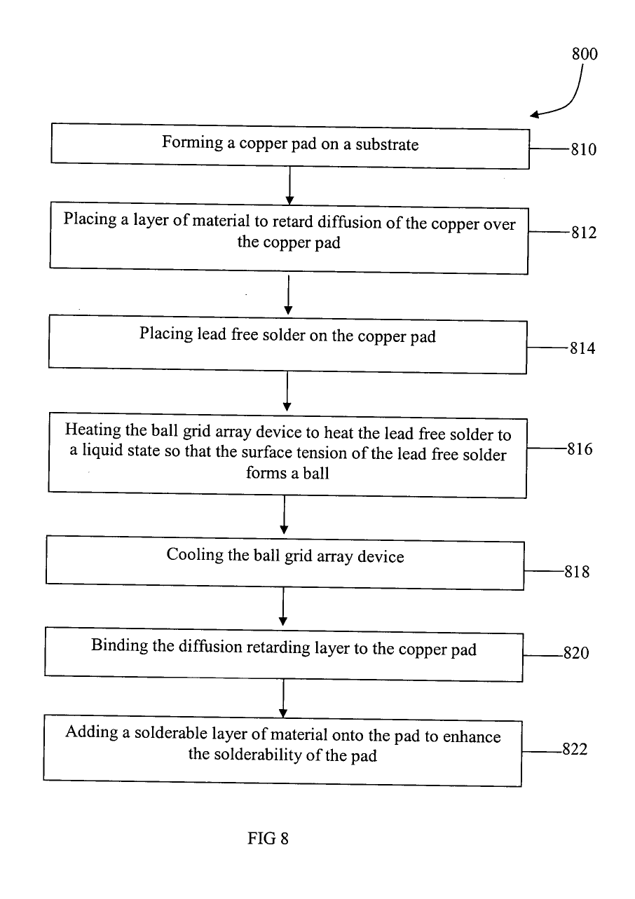

FIG. 7 is a flow diagram of a method 700 of forming a pad on an electronic device, according to an embodiment of this invention. The method 700 for forming a pad on an electronic device includes forming a copper pad on the electronic device 710, and placing a layer of material to retard diffusion of the copper over the copper pad 712. In some embodiments, placing a layer of material to retard diffusion of the copper into the solder ball includes adding a layer of material to bind the layer of material to retard diffusion of the copper 714. In other embodiments, a layer of a material to enhance the solderability of the pad is placed onto the layer of material to retard diffusion 716. The method 700 can also include binding the pad and the layer of material to retard diffusion with a binding material, and adding a solderable layer of material onto the pad to enhance the solderability of the pad.

The method 800 for forming a bump on a ball grid array device includes forming a copper pad on a substrate 810, placing a layer of material to retard diffusion of the copper over the copper pad 812, placing lead free solder on the copper pad 814, heating the ball grid array device to heat the lead free solder to a liquid state 816 so that the surface tension of the lead free solder forms a ball, and cooling the ball grid array device 818. The method 800 further includes binding the diffusion retarding layer to the copper pad 820 with a binding layer of titanium (Ti). The titanium is placed on the copper pad. In some embodiments, the method further includes placing a layer of gold on the diffusion retarding layer 822 to enhance the ability of the pad to receive solder.

A ball grid array device includes a substrate having a first major surface, and a second major surface. The substrate includes an array of pads made of an electrically conductive material. The array of pads is positioned on the first major surface. At least one of the array of pads includes a diffusion retarding layer to retard the rate of diffusion of the electrically conductive material from the pad. The ball grid array device also includes a binding layer for binding the diffusion retarding layer to the conductive material of the at least one pad. The ball grid array device also includes a layer of material for receiving solder placed on the diffusion retarding layer. In some embodiments, the electrically conductive of the pad includes copper and the diffusion retarding layer includes Kovar®. In other embodiments, the diffusion retarding layer includes 54Fe-29Ni-17Co. The binding layer includes titanium (Ti) or simply is titanium (Ti). In some embodiments, the titanium binding layer has a thickness in the range of 80 nanometers (nm) to 120 nanometers (nm). In other embodiments, the titanium binding layer has a thickness in the range of 90 nanometers (nm) to 110 nanometers (nm). The layer of material for receiving solder includes gold (Au) or is gold (Au).

A substrate includes at least one pad of a copper material, a diffusion retarding layer placed over the at least one pad, and a layer of gold over the at least one pad diffusion retarding layer. In some embodiments, the diffusion retarding layer includes Kovar®. In other embodiments, the diffusion retarding layer includes 54Fe-29Ni-17Co. The substrate also includes a layer of titanium (Ti) used to bond the diffusion retarding layer to the material of the at least one pad. The substrate, in some embodiments, also includes a plurality of pads arranged in an array.

A ball grid array device includes a substrate including a first major surface having an array of pads made of an electrically conductive material positioned on the first major surface, and solder placed on at least one of the array of pads. The solder and the pad include an intermetallic compound including Ni—Sn (Ni₃Sn₄) and Sn—Fe. The solder, in some embodiments, is lead-free.

The foregoing description of the specific embodiments reveals the general nature of the invention sufficiently that others can, by applying current knowledge, readily modify and/or adapt it for various applications without departing from the generic concept, and therefore such adaptations and modifications are intended to be comprehended within the meaning and range of equivalents of the disclosed embodiments.

It is to be understood that the phraseology or terminology employed herein is for the purpose of description and not of limitation. Accordingly, the invention is intended to embrace all such alternatives, modifications, equivalents and variations as fall within the spirit and broad scope of the appended claims.

1. A ball grid array device comprising:
a substrate, further including:
a first major surface; and
a second major surface; and
an array of pads made of an electrically conductive material, the array of pads positioned on the first major surface; and
a solder ball formed on at least one of the array of pads, at least one of the array of pads including a solderable diffusion retarding layer for controlling the out-diffusion of the electrically conductive material from the at least one pad during a solder reflow process.

2. The ball grid array device of claim 1 further comprising a binding layer for binding the diffusion retarding layer to the conductive material of the at least one pad.

3. The ball grid array device of claim 2 further comprising a layer of material for receiving solder.

4. The ball grid array device of claim 2 further comprising a layer of material for receiving solder placed on the diffusion retarding layer.

5. The ball grid array device of claim 1 wherein the electrically conductive of the pad includes copper.

6. The ball grid array device of claim 1 wherein the diffusion retarding layer includes Kovar®.

7. The ball grid array device of claim 1 wherein the diffusion retarding layer includes 54Fe-29Ni-17Co.

8. The ball grid array device of claim 2 wherein the binding layer includes Titanium (Ti).

9. The ball grid array device of claim 2 wherein the binding layer is Titanium (Ti).

10. The ball grid array device of claim 9 wherein the Titanium binding layer has a thickness in the range of 80 nanometers (nm) to 120 nanometers (nm).

11. The ball grid array device of claim 9 wherein the Titanium binding layer has a thickness in the range of 90 nanometers (nm) to 110 nanometers (nm).

12. The ball grid array device of claim 4 wherein the layer of material for receiving solder includes gold (Au).

13. The ball grid array device of claim 4 wherein the layer of material for receiving solder is gold (Au).

14. A substrate comprising:
at least one pad of a copper material;
a diffusion retarding layer placed over the at least one pad; and
a layer of gold over the at least one pad diffusion retarding layer.

15. The substrate of claim 14 wherein the diffusion retarding layer includes 54Fe-29Ni-17Co.

16. The substrate of claim 14 further comprising a layer of titanium (Ti) used to bond the diffusion retarding layer to the material of the at least one pad.

17. The substrate of claim 14 wherein the diffusion retarding layer includes 54Fe-29Ni-17Co, the substrate further comprising a layer of titanium (Ti) used to bond the diffusion retarding layer to the material of the at least one pad.

18. The substrate of claim 14 further comprising a plurality of pads.

19. The substrate of claim 14 further comprising a plurality of pads arranged in an array.

20-27. (Canceled)

28. A ball grid array device comprising:
a substrate including a first major surface, the substrate further including an array of pads made of an electrically conductive material, the array of pads positioned on the first major surface;
a diffusion retarding layer placed on at least one of the array of pads: and
solder placed on at least one of the array of pads, the solder and the pad including a intermetallic compound including Ni—Sn (Ni₃Sn₄) and Sn—Fe.

29. The ball grid array device of claim 28 wherein the solder is lead-free.

30. The ball grid array device of claim 28 wherein the pad includes a layer of gold.

31. An electronic device comprising:
a copper pad on the electronic device; and
means to retard diffusion of the copper associated with the copper pad adapted to retard the out-diffusion of the copper from the pad during a solder reflow process.

32. The electronic device of claim 31 wherein the means to retard diffusion of the copper includes a layer of binding material.

33. The electronic device of claim 31 further comprising a layer of solderability enhancing material attached to the means to retard diffusion.

34. The electronic device of claim 31 further comprising
means for binding the pad and the means to retard diffusion; and
a solderable layer of material attached to the copper pad.

35. A ball grid array device comprising:
a substrate;
a copper pad on the substrate;
means to retard diffusion of the copper associated with the copper pad; and
a solder ball attached to the copper pad.

36. The ball grid array device of claim 35 wherein the solder ball is formed from a lead free material.

37. The ball grid array device of claim 35 further comprising a binder for attaching the means to retard copper to the copper pad.

38. The ball grid array device of claim 37 wherein the binder includes a layer of titanium (Ti) on the copper pad.

39. The ball grid array device of claim 35 further comprising a layer of gold associated with the means to retard diffusion of copper.

40. A substrate comprising:
at least one pad of a copper material;
a solderable diffusion retarding layer placed over the at least one pad; and
a layer of gold over the at least one pad diffusion retarding layer,
